(19) United States
(12) Patent Application Publication
(10) Pub. No.: US 2025/0140604 A1
(43) Pub. Date: May 1, 2025

(54) VIA SHAPING BETWEEN METAL LAYERS FOR CONTROLLED RESISTANCE

(71) Applicant: Applied Materials, Inc., Santa Clara, CA (US)

(72) Inventors: Sefa Dag, Fremont, CA (US); El Mehdi Bazizi, San Jose, CA (US); Martinus Maria Berkens, Eindhoven (NL); Steven Sherman, Waltham, MA (US); Vinod Reddy, San Jose, CA (US)

(73) Assignee: Applied Materials, Inc., Santa Clara, CA (US)

(21) Appl. No.: 18/497,096

(22) Filed: Oct. 30, 2023

(51) Int. Cl. H01L 21/768; H01L 21/311; H01L 23/522; H01L 23/528; H01L 23/64

(52) U.S. Cl. CPC H01L 21/76804; H01L 21/31116; H01L 21/31144; H01L 23/5226; H01L 23/5283; H01L 23/647

(57) ABSTRACT

This disclosure describes structures and methods for forming tapered vias between features in metal layers in semiconductor devices. Instead of straight vias that have 90° vertical sidewalls and a constant cross-sectional area throughout the height of the via, tapered vias may be formed that extend outward from one metal layer to a lower metal layer. The via may be allowed to expand in size in a direction parallel to the feature in the lower metal layer, while remaining a constant width so as not to expand beyond the footprint of the lower feature. This tapered shape results in a larger cross-sectional area at the interface between the via and the lower feature. This lowers the resistance of the via by increasing area for current flow, while also increasing the area of any liners which typically have higher resistances.

### TECHNICAL FIELD

This disclosure generally describes vias between metal layers. More specifically, this disclosure describes a self-alignment process for decreasing the resistance between metal layers.

### BACKGROUND

In integrated circuits and semiconductor technology, a via is a vertical electrical connection that passes through one or more layers of a semiconductor device, enabling the transfer of electrical signals between different layers of the device. As the complexity of integrated circuits increases, designers use multiple metal layers to route signals efficiently. Vias enable these different metal layers to communicate, ensuring proper functionality of the integrated circuit. For example, a via is typically surrounded by a dielectric material (insulator), often made of materials like silicon dioxide (SiO₂) or other low-k dielectrics. This dielectric material isolates the via from adjacent conductive structures, preventing unwanted electrical interactions. The via hole is then filled with a conductive material, often tungsten (W) or copper (Cu), to establish an electrical connection between the metal layers. This conductive material forms a seamless bridge between the metal lines in different layers. Once fabricated, the via allows electrical signals to pass vertically between metal layers. When a signal needs to move from one layer to another (for instance, from metal layer M1 to M2), it travels through the via, establishing a connection without interfering with adjacent circuitry.

### SUMMARY

In some embodiments, a method of forming tapered vias between metal layers in semiconductor devices may include forming a first mask over a substrate, where the first mask may include a first pattern for a first feature, and the substrate may include a first insulator layer, a second insulator layer under the first insulator layer, and a metal layer under the second insulator layer, where the metal layer may include a second feature. The method may also include removing a portion of the first insulator layer that is exposed through the first mask to define the first feature in the second insulator layer. The method may additionally include forming a second mask over the substrate, where the second mask may include a second pattern for a via that connects the first feature to the second feature. The method may further include performing a directional etch through the second mask and the first insulator layer to define a recess for the via such that a first cross-sectional area of the via at the first feature is smaller than a second cross-sectional area at the second feature.

In some embodiments, a semiconductor device may include a first metal layer comprising a first feature; a second metal layer comprising a second feature, where the second metal layer is beneath the first metal layer; and an insulating layer between the first metal layer and the second metal layer, where the insulating layer may include a via connects the first feature to the second feature. The via may include a first cross-sectional area at the first feature; and a second cross-sectional area at the second feature, where the first cross-sectional area may be smaller than the second cross-sectional area.

In some embodiments, a semiconductor device may include a first metal layer comprising a first feature; a second metal layer comprising a second feature, where the second metal layer is beneath the first metal layer; and an insulating layer between the first metal layer and the second metal layer, where the insulating layer includes a via that connects the first feature to the second feature, and the via tapers outwards from the first feature at an angle of between about 10° and about 35°.

In any embodiments, any and all of the following features may be implemented in any combination and without limitation. The first mask may be removed before forming the second mask, where an opening in the second pattern for the via may overlap with an opening in the first pattern for the first feature. The opening in the second pattern for the via may be larger than the opening in the first pattern for the first feature. The directional etch may include a directional reactive-ion etch (RIE), and an angle of the directional RIE may define a taper of the recess for the via. A first liner may be formed in the recess for the via; a second liner may be formed over the first liner in the recess for the via, and the recess for the via may be filled with a conductive fill material inside the second liner. The first liner may include titanium nitride, the second liner may include cobalt, and the conductive fill material may include copper. The directional etch may be selective to the second insulator layer relative to the first insulator layer, such that the directional etch may etch the second insulator layer faster than the first insulator layer. The substrate may include an etch stop layer between the first insulator layer and the second insulator layer, and removing the portion of the first insulator layer may include etching the first insulator layer that is exposed through the first mask until the etch stop layer is exposed. The first insulator layer may form a first metal layer when the first feature is formed in the first insulator layer. The first feature may include a first conductive wire in a first metal layer, the second feature may include a second conductive wire in the metal layer, and the first conductive wire may run in a direction that is orthogonal to the second conductive wire. The first cross-sectional area may have a width equal to a width of the first feature, and a length equal to a width of the second feature. The second cross-sectional area may have a width equal to a width of the second feature, and a length that is greater than a width of the first feature. The via may continuously taper to become larger in a direction parallel to the second feature as the via extends from the first cross-sectional area to the second cross-sectional area. The semiconductor device may also include one or more liners that form an interface between the via and the second feature. The semiconductor device may also include a titanium nitride liner and a cobalt liner surrounding a copper fill material in the via. A resistance of the via may be between about 13.5 ohms and about 23 ohms. A resistance of the via may be reduced by between about 25% and about 45% in comparison to a second via that does not taper between the first feature and the second feature. A length of the via along the first feature may be equal to a width of the second feature plus twice the height of the via multiplied by a tangent of the angle.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIGS. 1A-1B illustrate the use of a via having a uniform cross-sectional area throughout its height, according to some embodiments.

FIGS. 2A-2B illustrate the use of a via having a nonuniform cross-sectional area throughout its height, according to some embodiments.

FIG. 3 illustrates a cross-sectional view of the tapered via, according to some embodiments.

FIG. 4 illustrates a graph of the reduction in the resistance of the via based on the angle θ, according to some embodiments.

FIG. 5 illustrates a flowchart of a method for forming tapered vias between metal layers in semiconductor devices.

FIGS. 6A-6H illustrate an example semiconductor substrate on which a tapered via may be formed.

### DETAILED DESCRIPTION

This disclosure describes structures and methods for forming tapered vias between features in metal layers in semiconductor devices. Instead of straight vias that have 90° vertical sidewalls and a constant cross-sectional area throughout the height of the via, tapered vias may be formed that extend outward from one metal layer to a lower metal layer. The via may be allowed to expand in size in a direction parallel to the feature in the lower metal layer, while remaining a constant width so as not to expand beyond the footprint of the lower feature. This tapered shape results in a larger cross-sectional area at the interface between the via and the lower feature. This lowers the resistance of the via by increasing area for current flow, while also increasing the area of any liners which typically have higher resistances.

Vias are small holes or openings that are formed through the layers of a semiconductor material during the manufacturing process of electronic devices. Vias are usually used in creating the complex interconnected network of electrical paths that make up modern electronic circuits. In some cases, multiple layers of vias may be used to create complex three-dimensional structures that allow for efficient routing of electrical signals. These multi-layer vias are created by depositing and patterning additional layers of conductive material on top of the initial layer to extend through any subsequent layers. Vias are crucial in modern semiconductor processing as they enable the creation of complex and highly integrated circuits that can contain thousands or even millions of individual components.

Overall, the process of forming vias is critical to the creation of complex and highly integrated circuits in modern electronic devices. The process requires precise control of the photolithography process used to pattern the metal or other conductive material that will form the via, as well as careful control of the etching process to ensure that the via is correctly aligned, properly filled, and has the appropriate dimensions to meet the required performance specifications.

The process of forming vias typically involves depositing a layer of metal or other conductive material onto the surface of the semiconductor material. A layer of photoresist is then applied to the metal layer. The photoresist is then exposed to ultraviolet light through a photomask, which defines the location and size of the via. The exposed photoresist is then removed, leaving a patterned layer of photoresist on top of the metal layer. The metal layer is then etched using an etch process (e.g., a chemical or plasma process), which removes the metal in the areas not covered by the photoresist, thereby creating the via. After the via has been created and the remaining photoresist is removed, the via may be cleaned to ensure that there are no residual contaminants or debris. In some cases, multiple layers of vias may be needed to create complex three-dimensional structures that allow for efficient routing of electrical signals. These multi-layer vias are created by depositing and patterning additional layers of conductive material on top of the initial layer.

However, the formation of vias can be challenging due to several factors. A first challenge is ensuring that the via is correctly aligned with the underlying circuitry. This requires precise control of the photolithography process used to pattern the metal or other conductive material that will form the via. Any misalignment can result in short circuits or other defects that can render the device non-functional. A second challenge is ensuring that the via is properly filled with the conductive material. This is particularly important for smaller vias, which can be difficult to fill completely. Incomplete filling can lead to voids or other defects that can affect the performance of the device. A third challenge is minimizing the resistance of the via. The resistance of the via can affect the performance of the device, particularly for high-frequency applications. To minimize resistance, the via should be designed with the appropriate dimensions and filled with the appropriate material.

To address these challenges, semiconductor manufacturers have developed a range of techniques for forming vias. These include chemical and mechanical methods for etching the via, as well as a variety of materials and techniques for filling the via. Manufacturers also use advanced modeling and simulation tools to optimize the design of vias and ensure that they meet the required performance specifications. However, none of these techniques have been shown to effectively lower the resistance of the via. This is important because lowering the via resistance is often a key factor in improving performance of the electrical device. Generally, the lower the resistance, the better the chip performs.

The via resistance depends primarily on the dimensions of the via, including the width, length, and height of the via in three dimensions. A taller via (i.e., in the vertical direction between layers) creates a longer conductive path and thereby increases the resistance of the via. However, a wider via (i.e., having a larger cross-sectional area in the horizontal direction) creates a larger area for current flow and thereby decreases the resistance of the via. Therefore, the embodiments described herein solve the technical problem of lowering the via resistance by widening the via dimensions using techniques that do not adversely affect the manufacturing process, the alignment of the via, or the performance of the electronic device.

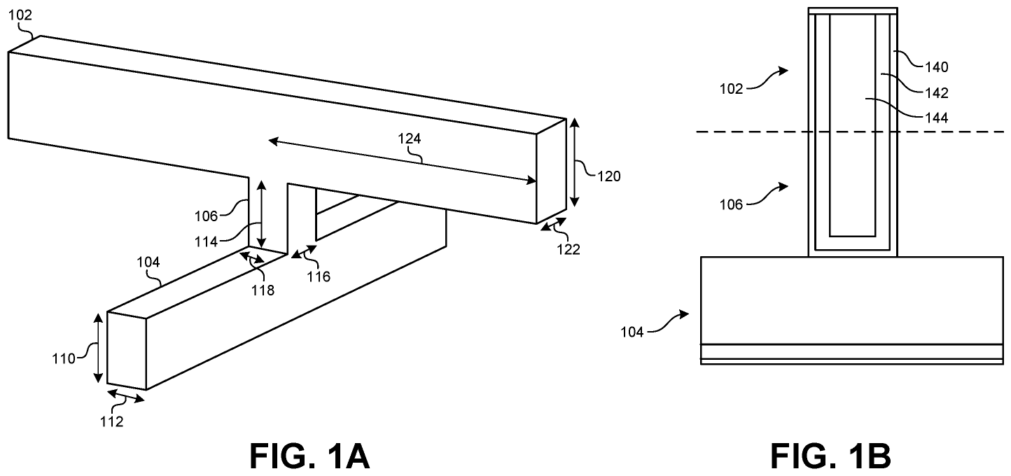

FIGS. 1A-1B illustrate the use of a via having a uniform cross-sectional area throughout its height, according to some embodiments. This example shows two metal layers separated by an insulating layer and connected through a via. The underlying metal layer may be referred to as an M0 layer. The M0 layer may include a number of metal features representing conductive connections (e.g., wires, planes, contacts, etc.), such as a feature referred to herein as an M0 feature 104. The overlying metal layer may be referred to as an M1 layer. The M1 layer may include a number of metal features representing conductive connections, such as a feature referred to herein as an M1 feature 102. In this example, the M0 feature 104 may include a conductive wire oriented in a first direction, and the M1 feature 102 may include a conductive wire oriented in a second direction, where the first direction is approximately orthogonal to the second direction.

Note that the M0 layer and the M1 layer described herein are used only by way of example and are not meant to be limiting. More generally, the M0 layer may represent a lower metal layer (or a “first” layer) that is formed first in semiconductor device, and the M1 layer may represent a higher metal layer (or a “second” layer”) that is formed after the lower metal layer. Without limitation, many additional layers may be present between the first layer and the second layer. These layers may include dielectric layers, insulating materials, device layers, or even other interconnect metal layers. For example, the first layer may include an M0 layer, and the second layer may include an M2 layer. The via in this example may run between the M0 layer and the M2 layer with an M1 layer between these layers. Therefore, the M0 and M1 layers used as an example below may be freely substituted with a more generic first layer and second layer of conductive materials.

A via 106 may connect the M0 feature 104 to the M1 feature 102. Although not illustrated in these figures, dielectric or insulating layers may be formed to surround each of these conductive components. For example, an insulating layer may be formed on top of the M0 layer, a hole may be formed in the insulating layer to expose the M0 layer, the hole may be filled with the metal for the via 106, and the M1 layer may be formed in and on top of the via 106 and on top of the insulating layer. The via 106 connecting the M0 feature 104 and the M1 feature 102 may be formed relative to the M1 feature 102 to ensure that the via 106 is automatically aligned with the M1 feature 102. More specifically, a series of process steps may be used in a “self-alignment” process to ensure that the via 106 is directly underneath and aligned with the M1 feature 102 so as not to be extruding out from the outline of the M1 feature 102.

The dimensions of the various layers illustrated in FIG. 1A are provided here only by way of example and are not meant to be limiting. For example, the M1 feature 102 may have a height 120 of between about 15 nm and about 45 nm, with some embodiments having a height 120 of about 30 nm. The M1 feature 102 may have a width 122 of between about 40 nm and about 10 nm, with some embodiments having a width 122 of about 19.5 nm. The M0 feature 104 may have a height 110 of between about 10 nm and about 40 nm, with some embodiments having a height 110 of about 24 nm. The M0 feature 104 may have a width 112 of between about 10 nm and about 30 nm, with some embodiments having a width 110 of about 14.5 nm. The via 106 may have a height 114 of between about 10 nm and about 40 nm, with some embodiments having a height 114 of about 24 nm. Traditionally, the width 118 and the length 116 of the via 106 have been determined entirely on the corresponding widths of the M0 feature 104 and the M1 feature 102, respectively. For example, the via 106 may have a width 118 of between about 10 nm and about 30 nm, with some embodiments having a width 118 of about 14.5 nm. The via 106 may also have a length 116 of between about 40 nm and about 10 nm, with some embodiments having a length 116 of about 19.5 nm.

Conductive metals such as copper may be used primarily for the fill materials in the M0 feature 104, the M1 feature 102, and/or the via 106. However, using only copper may leave the circuit open to electromigration problems. Electromigration is a process that occurs when high-density electric currents flow through metallic conductors. During this process, the metal atoms can be displaced from their lattice positions, causing voids or defects to form in the metal. This is caused primarily by the interaction of electrons with metal atoms in the conductor. As high-density currents flow through the conductor, the electrons collide with metal atoms, causing them to migrate in the direction of the electron flow. The effects of electromigration are particularly pronounced in narrow metal lines and in regions where the current density is high, such as the via 106 and/or the M0 feature 104 and the M1 feature 102.

To mitigate the effects of electromigration, a variety of techniques may be used such as increasing the width of metal lines, reducing the current density, or using alternative materials that are less susceptible to electromigration. Therefore, some embodiments may use various liner materials to surround the copper conductors to prevent or reduce electromigration. For example, when forming the via 106, the M0 feature 104, and/or the M1 feature 102, a first liner 140 may be formed from titanium nitride or other similar materials. The thickness of the first liner 140 may be between about 1.0 nm and 3.0 nm, with some embodiments having a thickness of about 1.5 nm. In some embodiments, a second liner 142 may be formed from cobalt or other similar materials. The thickness of the second liner 142 may be between about 1.0 nm and 5.0 nm, with some embodiments having a thickness of about 3.0 nm. After these layers are formed, a conductive core 144 may be formed from copper or other similar fill materials. Note that the use of two liners and/or the materials specified for these liners is provided only by way of example and is not meant to be limiting. Other embodiments may use one liner, two liners, three liners, or more. These features may be formed from any conductive material.

As illustrated in FIG. 1B, the first liner 140, the second liner 142, and the conductive core 144 may be formed in the via 106 and the M1 feature 102 as part of a unified process. Therefore, no liner needs to be placed between the via 106 and the M1 feature 102. However, these liners will exist between the via 106 and the M0 feature 104. For example, the copper of the conductive core in the M0 feature 104 may be separated from the copper of the conductive core 144 of the via 106 by the first liner 140 and/or the second liner 142. Thus, while a liner interface need not exist between the M1 feature 102 and the via 106, a liner interface may exist between the M0 feature 104 and the via 106. It has been discovered that the resistance of copper is lower than the resistance of both of the liner materials. Therefore the intersection where the via 106 contacts the M0 feature 104 has a higher resistance than the interface between the via 106 and the M1 feature 102.

The alignment procedure described above does not allow the location or the dimension of the via 106 to be adjusted at the interface between the via 106 and the M1 feature 102. This prevents the cross-sectional area of the via 106 from being increased at the top of the via 106 in order to decrease the resistance through the via 106. However, the embodiments described herein may adjust the dimensions of the via 106 at the bottom of the via 106 at the interface with the M0 feature 104. Specifically, this self-alignment process will allow the location of the via 106 to shift relative to the M0 feature 104 with some modifications to the manufacturing process. By increasing the cross-sectional area of the via 106 at the interface with the M0 feature 104, the resistance of the via 106 may be reduced. Since the resistance through the first liner is higher than the resistance of the conductive core 144, increasing the cross-sectional area of the liners may significantly reduce the overall resistance through the via 106.

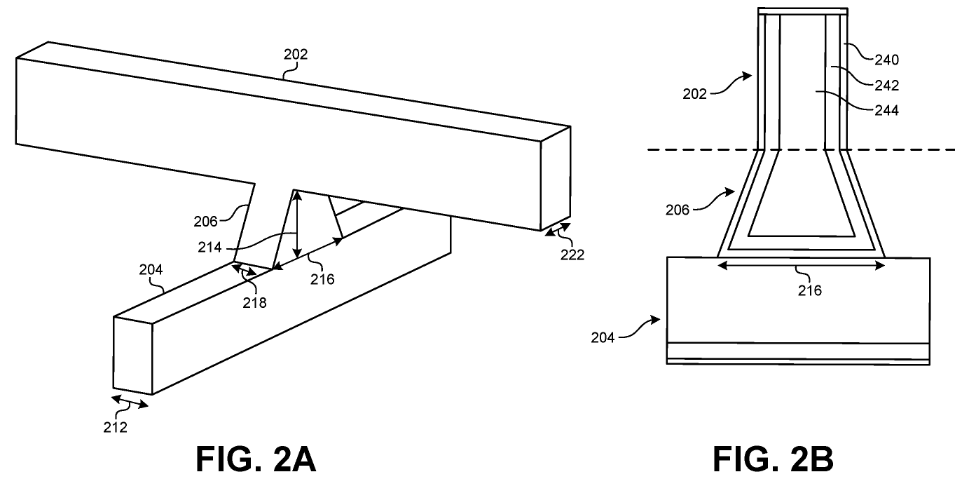

FIGS. 2A-2B illustrate the use of a via having a nonuniform cross-sectional area throughout its height, according to some embodiments. In order to decrease the resistance through the liners, the shape of the via 206 may be tapered. For example, the length 216 of the via 206 may grow larger as the via 206 extends down from the M1 feature 202 to the M0 feature 204. The length 216 at the top of the via 206 may be approximately equal to the width 222 of the M1 feature 202. However, the length 216 at the bottom of the via 206 may grow to be larger than the width 222 of the M1 feature 202.

In contrast, the width 218 of the via 206 may remain constant and approximately equal to the width 212 of the M0 feature 204 throughout the height 214 of the via 206. In some embodiments, the constant width 218 of the via 206 may be used in order to prevent an accidental short with another wire or feature in the M0 layer. Therefore, the width 218 of the via 206 may remain constant, or may at least remain less than or equal to the width 212 of the M0 feature 204. As illustrated in FIG. 2B, increasing the length 216 of the via 206 may also increase the cross-sectional area or surface area of the first liner 240 and the second liner 242. This increased area of these liners decreases the resistance through the interface between the via 206 and the M0 feature 204. More generally, the length of the via may expand in the direction of the lower feature to stay within the footprint of the lower feature while expanding outside of the footprint of the upper feature.

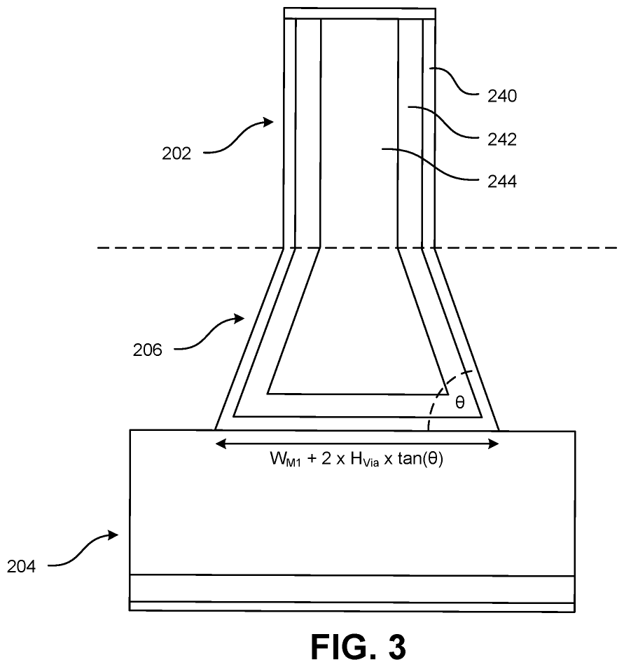

FIG. 3 illustrates a cross-sectional view of the tapered via, according to some embodiments. In some cases, it may be beneficial to characterize the tapering effect or increase in the length 216 of the via 206 in terms of a taper angle θ. For example, the length of the via 206 may be equal to the width 222 of the M1 feature 202 (i.e., the center section of the length 216 of the via 206) plus two times the height 214 of the via 206 multiplied by the tangent of the angle θ. As the angle θ increases, the length 216 may also increase proportional to the tangent function of the angle θ.

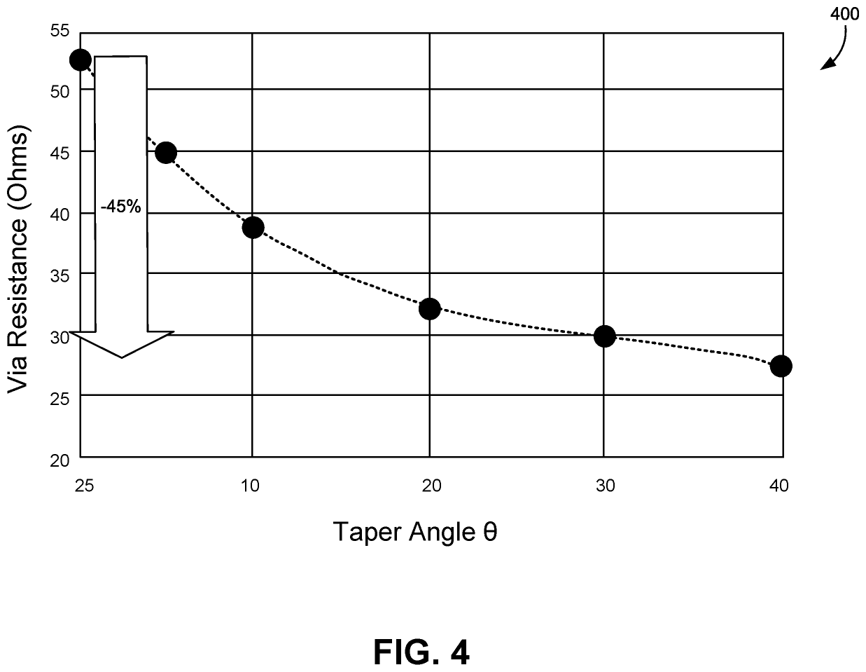

FIG. 4 illustrates a graph of 400 the reduction in the resistance of the via based on the angle θ, according to some embodiments. The y-axis of the graph 400 represents the via resistance as measured in ohms. The x-axis of the graph 400 represents the taper angle θ described above in FIG. 3. As shown in the graph 400, increasing the taper angle decreases the resistance through the via. For example, when the taper angle θ is approximately 10°, the resistance of the via is decreased by approximately 13.5 ohms, representing a decrease of approximately 25%. When the taper angle θ is approximately 35°, the resistance of the via is decreased by approximately 23 ohms, representing a decrease of approximately 45%. As described below, the directional etch used to form the recess for the via 206 may perform best at an angles between about 10° and about 35°.

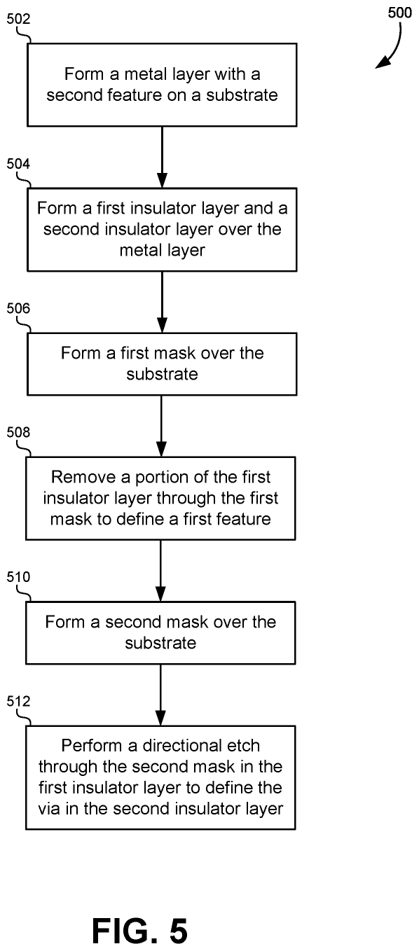

FIG. 5 illustrates a flowchart 500 of a method for forming tapered vias between metal layers in semiconductor devices. This method may be executed by one or more semiconductor processing chambers or stations. For example, a semiconductor processing station may include a deposition chamber, an etch chamber, a plating chamber, and so forth. The semiconductor processing chambers may include controllers that control the operation of the processing aspects of the chambers. For example, the controller(s) may include one or more processors and one or more memory devices (e.g., non-transitory computer-readable media) that store instructions. These instructions may cause the one or more processors to perform operations described below, such as forming metal layers, forming insulator layers, forming mask layers, removing various layers, performing etches, performing directional etches, and so forth. Therefore, the instructions that implement this method may be performed by a single central controller or by a plurality of distributed controllers, each corresponding to a specific type of semiconductor processing station.

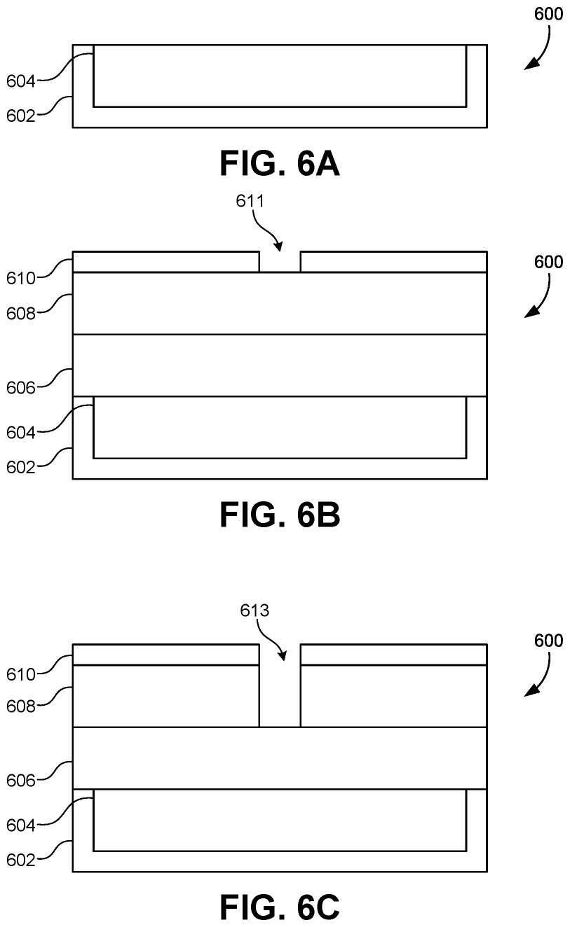

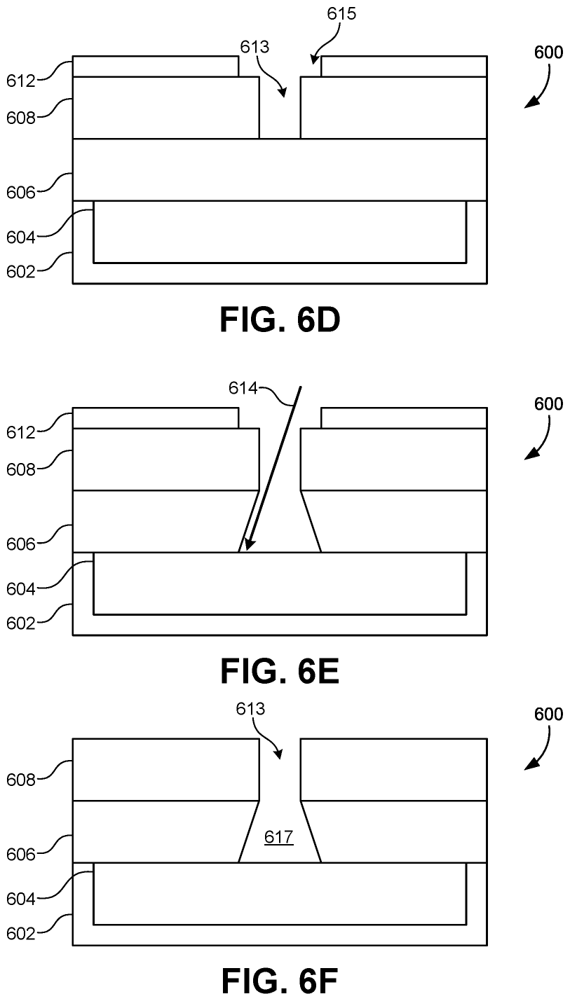

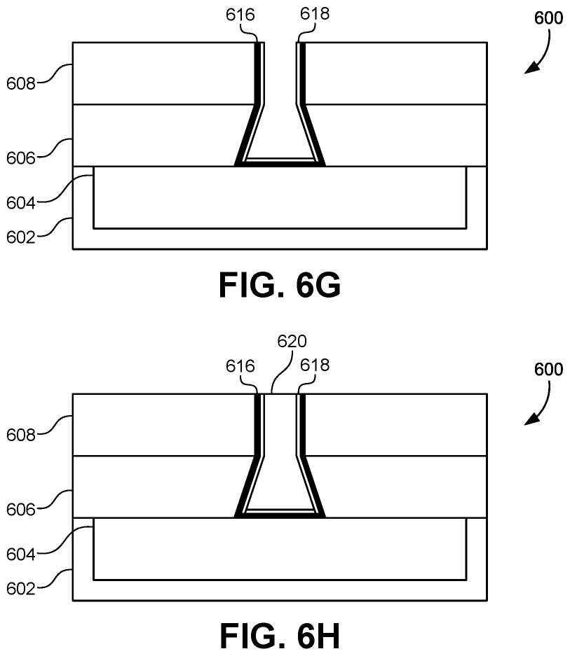

In order to illustrate various operations that may be performed, FIGS. 6A-6H illustrate an example semiconductor substrate on which a tapered via may be formed. Note that the various layers depicted in FIGS. 6A-6H are provided only by way of example and are not meant to be limiting. Other layers may be present within the semiconductor stack, including layers between the illustrated layers that are not explicitly illustrated in these figures. Therefore, in some embodiments the illustrated layers in these figures may be formed directly adjacent to each other and in direct physical contact with each other, having with no intervening layers. However, other embodiments may allow other intervening layers to be present without limitation unless specified otherwise.

The method may include forming a metal layer with a second feature over a substrate (502). FIG. 6A illustrates a metal layer 602 that includes a feature 604. For example, the feature 604 may include a metal wire that runs parallel to the view illustrated in FIG. 6A such that the view represents a cross-sectional area of the metal wire. The metal wire may include a copper wire or other conductive metals. Although not shown explicitly, the metal layer 602 may be formed over a substrate, such as a silicon substrate, a glass substrate, and/or any other type of substrate. Other layers may also be present on the substrate below the metal layer 602, such as various device layers that may include transistors, capacitors, and/or other electronic components.

The metal layer 602 may include any metal interconnect layer, such as an M0 layer, an M1 layer, and so forth. In some embodiments, the metal layer 602 may represent a device interconnect layer, a global interconnect layer, a redistribution layer, a fanout layer, and/or any other connection layer. The metal layer 602 may include many other features not explicitly illustrated in FIG. 6A, such as other wires or connections, vias, device components, and so forth. The metal layer 602 may include an insulator material, such as a dielectric or other nonconductive material that runs between the various features to insulate, for example, one wire from another wire. The metal layer 602 may represent a metal layer that will receive the tapered via being formed from above by this method.

The method may also include forming a first insulator layer and a second insulator layer over the metal layer (504). FIG. 6B illustrates a first insulator layer 608 and a second insulator layer 606. The second insulator layer 606 may be under the first insulator layer 608, and the metal layer 602 may be under the second insulator layer 606. The insulator layers may be formed from any type of insulator material, including dielectrics such as silicon oxide, silicon nitride, and so forth. In some embodiments, the first insulator layer 608 and the second insulator layer 606 may be formed from different materials. This may allow later etch processes to selectively target the first insulator layer 608 without etching the second insulator layer 606, and vice versa. Some embodiments may also optionally include an etch stop layer between the first insulator layer 608 and the second insulator layer 606. As described below, the first insulator layer 608 may form another metal layer as various features are formed in the insulator material of the first insulator layer 608.

In some processes, the structure illustrated in FIG. 6B may be formed, and the method may optionally begin after the insulator layers are present. Therefore, some embodiments of this method need not include the formation of the insulator layers and the metal layer 602, but may instead begin with the structures already formed. In this case, the term “substrate” may refer to any layers in the semiconductor device stack that have been formed when the method begins.

The method may additionally include forming a first mask layer over the substrate (506). As described above, at this stage the substrate may now include the metal layer 602 with the feature 604, the second insulator layer 606, and/or the first insulator layer 608. The first mask layer 610 may include a pattern for a first feature to be formed in the first insulator layer 608. For example, an opening 611 in the first mask layer 610 may expose a portion of the first insulator layer 608 that defines a first feature to be formed in the first insulator layer 608. The first mask layer 610 may be deposited, and the pattern may be formed and opened in the first mask layer 610 using deposition and etch techniques.

The method may further include removing a portion of the first insulator layer that is exposed through the first mask to define the first feature 613 in the second insulator layer (508). FIG. 6C illustrates the first feature 613 formed in the first insulator layer 608, according to some embodiments. For example, the first feature 613 may include another copper wire that runs perpendicular or orthogonal to the wire represented by the feature 604 in the metal layer 602 (e.g., “out of the page” in the view of FIG. 6C.). For purposes of distinguishing one layer/feature from another, the metal layer 602 may also be referred to as a “second metal layer” and the feature 604 may also be referred to as a “second feature.” The first feature 613 may be defined in the first insulator layer 608 by executing any type of etch process, including a dry etch, a plasma-aided etch, a wet etch, and so forth. This etch process may be selective to the insulator material of the first insulator layer 608. This allows the etch process to remove the material of the first insulator layer 608 without significantly removing the material of the second insulator layer 606. As described above, some embodiments may also include an etch stop layer between the first insulator layer 608 and the second insulator layer 606. The etch process may be performed until the etch stop layer is reached.

The method may also include forming a second mask over the substrate (510). FIG. 6D illustrates the second mask 612 formed over the first insulator layer 608. The second mask 612 may define a second pattern for a via that connects the first feature 613 to the second feature 604. Although not illustrated explicitly, some embodiments may also include removing the first mask layer 610 before forming the second mask 612. For example, the pattern in the second mask 612 may include an opening 615 that defines the location for the via. The opening 615 in the second pattern may overlap with the opening in the first pattern for the first feature as illustrated in FIG. 6D. For example, the opening 615 in the second pattern may be the same size as the opening 611 in the first mask layer 610. Alternatively, the opening 615 may be larger than the opening 611, and consequently larger than the first feature 613. Since the etch performed to form the via will be selective to the second insulator layer 606, the exposed material of the first insulator layer 608 does not need to be completely covered by the second mask 612. This allows a degree of tolerance for the placement of the second mask 612 relative to the first insulator layer 608. This also automatically aligns the via formed in the second insulator layer 606 with the outline of the first feature 613 in the first insulator layer 608. Although not shown explicitly, some embodiments may also remove any etch stop layer between the first insulator layer 608 and the second insulator layer 606.

The method may additionally include performing a directional etch through the second mask and the first insulator layer to define a recess for the via (512). The directional etch may include a reactive-ion etch (RIE) performed such that the taper angle illustrated in FIG. 3 above is formed in the second insulator layer 606. For example, an angle of the directional RIE may define a taper of the recess for the via. The via may continuously taper in a linear fashion in a straight line. FIG. 6E illustrates the formation of a tapered via in the second insulator layer 606, according to some embodiments. For example, the via may be formed using a directional etch 614 such that a first cross-sectional area of the via at the first feature is larger than a second cross-sectional area at the second feature. The dimensions, shape, location, and other characteristics of the via may be formed as described in detail above in FIGS. 2A-4 and throughout this disclosure. The directional etch may be performed until the top surface of the second feature 604 is exposed in the second metal layer 602. The directional etch may also be selective to the second insulator layer 606 relative to the first insulator layer 608 such that the directional etch etches the second insulator layer 606 faster than the first insulator layer.

Optionally, the method may also include removing the second mask 612. FIG. 6F illustrates the semiconductor structure with the opening for the first feature 613 connected to the opening for the via 617. The method may optionally also include forming a first liner in the recess for the via 617, and/or forming a second liner over the first liner in the recess for the via 617. FIG. 6G illustrates the formation of a first liner 616 and a second liner 618. These layers may be formed and have dimensions as described in detail above. For example, the first liner may include titanium nitrite or other similar materials, and the second liner may include cobalt or other similar materials. The method may also optionally include filling the recess for the via 617 with the conductive filler material inside the second liner 618. FIG. 6H illustrates a fill procedure to form the via and the first feature, according to some embodiments. For example, the fill material may include copper, and is fill procedure may form the tapered via and the first feature together in a single process. In some embodiments, this fill process may use a dual damascene process or other electroplating process to provide the metal fill material. Note that the first insulator layer 608 may now also be referred to as a metal layer (e.g., an M1 layer) with the first feature formed in the material of first insulator layer 608. Therefore, this layer may be referred to as a first metal layer or a first insulator layer interchangeably during this manufacturing process and throughout this disclosure.

It should be appreciated that the specific steps illustrated in FIG. 5 provide particular methods of forming tapered vias between metal layers in semiconductor devices according to various embodiments. Other sequences of steps may also be performed according to alternative embodiments. For example, alternative embodiments may perform the steps outlined above in a different order. Moreover, the individual steps illustrated in FIG. 5 may include multiple sub-steps that may be performed in various sequences as appropriate to the individual step. Furthermore, additional steps may be added or removed depending on the particular applications. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

What is claimed is:

1. A method of forming tapered vias between metal layers in semiconductor devices, the method comprising:
forming a first mask over a substrate, wherein the first mask comprises a first pattern for a first feature, and the substrate comprises:
a first insulator layer;
a second insulator layer under the first insulator layer; and
a metal layer under the second insulator layer, wherein the metal layer comprises a second feature;
removing a portion of the first insulator layer that is exposed through the first mask to define the first feature in the second insulator layer;
forming a second mask over the substrate, wherein the second mask comprises a second pattern for a via that connects the first feature to the second feature; and
performing a directional etch through the second mask and the first insulator layer to define a recess for the via such that a first cross-sectional area of the via at the first feature is smaller than a second cross-sectional area at the second feature.

2. The method of claim 1, further comprising:
removing the first mask before forming the second mask, wherein an opening in the second pattern for the via overlaps with an opening in the first pattern for the first feature.

3. The method of claim 2, wherein the opening in the second pattern for the via is larger than the opening in the first pattern for the first feature.

4. The method of claim 1, wherein the directional etch comprises a directional reactive-ion etch (RIE), and an angle of the directional RIE defines a taper of the recess for the via.

5. The method of claim 1, further comprising:
forming a first liner in the recess for the via;
forming a second liner over the first liner in the recess for the via; and
filling the recess for the via with a conductive fill material inside the second liner.

6. The method of claim 5, wherein:
the first liner comprises titanium nitride;
the second liner comprises cobalt; and
the conductive fill material comprises copper.

7. The method of claim 1, wherein the directional etch is selective to the second insulator layer relative to the first insulator layer, such that the directional etch etches the second insulator layer faster than the first insulator layer.

8. The method of claim 1, wherein the substrate further comprises an etch stop layer between the first insulator layer and the second insulator layer, and removing the portion of the first insulator layer comprises etching the first insulator layer that is exposed through the first mask until the etch stop layer is exposed.

9. The method of claim 1, wherein the first insulator layer forms a first metal layer when the first feature is formed in the first insulator layer.

10. The method of claim 1, wherein the first feature comprises a first conductive wire in a first metal layer, the second feature comprises a second conductive wire in the metal layer, and the first conductive wire runs in a direction that is orthogonal to the second conductive wire.

11. A semiconductor device comprising:
a first metal layer comprising a first feature;
a second metal layer comprising a second feature, wherein the second metal layer is beneath the first metal layer; and
an insulating layer between the first metal layer and the second metal layer, wherein the insulating layer comprises a via connects the first feature to the second feature, wherein the via comprises:
a first cross-sectional area at the first feature; and
a second cross-sectional area at the second feature, wherein the first cross-sectional area is smaller than the second cross-sectional area.

12. The semiconductor device of claim 11, wherein the first cross-sectional area comprises a width equal to a width of the first feature, and a length equal to a width of the second feature.

13. The semiconductor device of claim 11, wherein the second cross-sectional area comprises a width equal to a width of the second feature, and a length that is greater than a width of the first feature.

14. The semiconductor device of claim 11, wherein the via continuously tapers to become larger in a direction parallel to the second feature as the via extends from the first cross-sectional area to the second cross-sectional area.

15. The semiconductor device of claim 11, further comprising one or more liners that form an interface between the via and the second feature.

16. A semiconductor device comprising:
a first metal layer comprising a first feature;
a second metal layer comprising a second feature, wherein the second metal layer is beneath the first metal layer; and
an insulating layer between the first metal layer and the second metal layer, wherein the insulating layer comprises a via that connects the first feature to the second feature, wherein the via tapers outwards from the first feature at an angle of between about 10° and about 35°.

17. The semiconductor device of claim 16, further comprising a titanium nitride liner and a cobalt liner surrounding a copper fill material in the via.

18. The semiconductor device of claim 16, wherein a resistance of the via is between about 13.5 ohms and about 23 ohms.

19. The semiconductor device of claim 16, wherein a resistance of the via is reduced by between about 25% and about 45% in comparison to a second via that does not taper between the first feature and the second feature.

20. The semiconductor device of claim 16, wherein a length of the via along the first feature is equal to a width of the second feature plus twice the height of the via multiplied by a tangent of the angle.
